(19) United States
(12) Patent Application Publication
(10) Pub. No.: US 2016/0186054 A1
(43) Pub. Date: Jun. 30, 2016

(54) BORON NITRIDE PHOSPHOR, METHOD FOR MANUFACTURING THE SAME AND LIGHT EMITTING DEVICE PACKAGE INCLUDING THE SAME

(71) Applicant: LG ELECTRONICS INC., Seoul (KR)

(72) Inventor: Dongwon KANG, Seoul (KR)

(21) Appl. No.: 14/786,631

(22) PCT Filed: Aug. 19, 2014
(86) PCT No.: PCT/KR2014/007688

§ 371 Date: Oct. 23, 2015

(30) Foreign Application Priority Data
Sep. 2, 2013 (KR) 10-2013-0105098

(51) Int. Cl. C09K 11/77; H01L 33/50

(52) U.S. Cl. CPC C09K 11/7728; H01L 33/502; H01L 2933/0033; H01L 2933/0041

(57) ABSTRACT

Disclosed are a phosphor, in particular, a boron nitride phosphor, a method for manufacturing the same and a light emitting device package using the same. Provided is a boron nitride phosphor represented by the following Formula 1: [Formula 1] M₃₋ₓB_{1-y}N_{3-2/3x-y}:E wherein M represents an alkaline earth metal including at least one of Mg, Ca, Sr and Ba, and E represents an activator including at least one of Eu, Ce, Pr, Mn and Bi, or a compound thereof.

### TECHNICAL FIELD

The present invention relates to a boron nitride phosphor, a method for manufacturing the same and a light emitting device package including the same.

### BACKGROUND ART

Light emitting diodes (LEDs) emitting white light are next-generation light emitting device candidates which can replace fluorescent lights as the most representative conventional lights.

Light emitting diodes have low power consumption as compared to conventional light sources and are environmentally friendly because they do not contain mercury, unlike fluorescent lights. In addition, light emitting diodes have advantages of long lifespan and high response speed as compared to conventional light sources.

There are three methods for producing white light emitting diodes. These methods include implementation of white light by combination of red, green and blue LEDs, implementation of white light by applying a yellow phosphor to blue LEDs and implementation of white light by combination of red, green and blue LEDs with a UV LED.

Of these, the implementation of white light by applying the yellow phosphor to blue LEDs is the most representative method for obtaining white light using light emitting diodes.

Alkaline earth silicate phosphors activated with europium (Eu) and manganese (Mn) such as (Sr,Ba,Mg)₂SiO₄:Eu,Mn are known as green or yellow phosphors for white LED lamps.

The production of such a phosphor is not easy because it requires high-temperature and high-pressure production processes and uses explosive precursors.

In addition, there is demand for phosphors having various properties in addition to the phosphors described above.

### DISCLOSURE

### Technical Problem

An object of the present invention devised to solve the problem lies on a boron nitride phosphor providing a phosphor having a novel light emission function, a method for producing the same and a light emitting device package using the same.

Another object of the present invention devised to solve the problem lies on a boron nitride phosphor that shortens an overall process time by a low-temperature, low-pressure process using a stable precursor, a method for producing the same and a light emitting device package using the same.

### Technical Solution

The object of the present invention can be achieved by providing a boron nitride phosphor represented by the following Formula 1:

M₃₋ₓB_{1-y}N_{3-2/3x-y}: E [Formula 1]

wherein M represents an alkaline earth metal including at least one of Mg, Ca, Sr and Ba, and E represents an activator including at least one of Eu, Ce, Pr, Mn and Bi, or a compound thereof.

The activator may be present in an amount of 0.1 wt % to 30 wt % with respect to the M₃₋ₓB_{1-y}N_{3-2/3x-y} matrix.

Meanwhile, x and y may satisfy 0<x<1 and 0<y<0.9.

In another aspect of the present invention, provided herein is a method for producing a boron nitride phosphor represented by the following Formula 1 using an alkaline earth metal, boron (B), nitrogen (N) and an activator.

M₃₋ₓB_{1-y}N_{3-2/3x-y}:E [Formula 1]

wherein M represents an alkaline earth metal including at least one of Mg, Ca, Sr and Ba, and E represents an activator including at least one of Eu, Ce, Pr, Mn and Bi, or a compound thereof.

The production of the phosphor may be carried out by gas pressure sintering (GPS).

The production of the phosphor may be carried out at a pressure of 0.1 to 0.9 MPa.

The production of the phosphor may be carried out by reacting at a pressure of 1,000° C. to 1,300° C. for 3 to 6 hours.

Upon increasing the temperature to the temperature range defined above, a rate of temperature increase per hour from the lower limit temperature to an intermediate temperature may be greater than a rate of temperature increase per hour from the intermediate temperature to the upper limit temperature.

In addition, upon decreasing the temperature to the temperature range defined above, a rate of temperature decrease per hour from the upper limit temperature to the intermediate temperature may be lower than a rate of temperature decrease per hour from the intermediate temperature to the lower limit temperature.

The activator may include a chloride activator.

The alkaline earth metal may be used as metal nitride.

The boron (B) and nitrogen (N) may be used as hexagonal boron nitride (h-BN).

In a further aspect of the present invention, provided herein is a method for producing a boron nitride phosphor including forming a Mg₃BN₃ structure as a matrix using Mg₃N₂ and boron nitride (BN) as precursors, and doping the matrix with an activator.

The boron nitride may include hexagonal boron nitride.

The activator may include a chloride activator.

The chloride activator may include EuCl₃, EuCl₂ or CeCl₃.

The chloride activator may be present in an amount of 0.1 wt % to 30 wt %, with respect to the weight of the matrix.

The production of the phosphor may be carried out by gas pressure sintering (GPS).

In a further aspect of the present invention, provided herein is a light emitting device package including the phosphor described above or a phosphor represented by Formula 1 produced by the method described above.

### Advantageous Effects

The present invention has the following advantages.

The present invention provides a metal-BN phosphor and a method for producing the same.

The metal-BN substance is not reported as a phosphor to date, but the present invention provides a novel phosphor substance.

The production of the phosphor substance is carried out by gas pressure sintering (GPS) capable of synthesizing a phosphor using a low pressure of 1 MPa or less.

Accordingly, the phosphor can be produced at a relatively low temperature using GPS.

In accordance with the method for producing the phosphor, the total process time can be reduced to 10 hours or less. This time is greatly shortened as compared to the conventional process time of 24 hours or longer.

The technical effects of the present invention are not limited to those described above and other effects not described herein will be clearly understood by those skilled in the art from the following description.

### DESCRIPTION OF DRAWINGS

The accompanying drawings, which are included to provide a further understanding of the invention, illustrate embodiments of the invention and together with the description serve to explain the principle of the invention.

In the drawings:

FIG. 1 is an XRD spectrum of a synthesized Mg₃BN₃ structure.

FIG. 2 is a schematic view illustrating a crystal structure model of the substance of FIG. 1.

FIG. 3 is an XRD spectrum of a synthesized Ca₃BN₄ structure.

FIG. 4 a schematic view illustrating a crystal structure model of the substance of FIG. 3.

FIG. 5 is an XRD spectrum of emitted Mg₃BN₃:Eu light.

FIG. 6 is an emission spectrum of emitted Mg₃BN₃:Eu light.

FIG. 7 is a schematic view illustrating an example of a light emitting device package using a metal-BN phosphor.

FIG. 8 is a schematic view illustrating another example of a light emitting device package using a metal-BN phosphor.

### BEST MODE

Reference will now be made in detail to the preferred embodiments of the present invention, examples of which are illustrated in the accompanying drawings.

However, the present invention allows various modifications and variations and specific embodiments thereof are exemplified with reference to the drawings and will be described in detail. The present invention should not be construed as limited to the embodiments set forth herein and includes modifications, equivalents and substitutions compliant with the spirit or scope of the present invention defined by the appended claims.

It will be understood that when an element such as a layer, area or substrate is referred to as being “on” another element, it may be directly on the element, or one or more intervening elements may also be present therebetween.

In addition, it will be understood that although terms such as “first” and “second” may be used herein to describe elements, components, areas, layers and/or regions, the elements, components, areas, layers and/or regions should not be limited by these terms.

The present invention provides a boron nitride (BN) phosphor.

Specifically, the present invention provides a boron nitride phosphor represented by the following Formula 1.

M₃₋ₓB_{1-y}N_{3-2/3x-y}:E [Formula 1]

wherein M represents an alkaline earth metal including at least one of Mg, Ca, Sr and Ba, and E represents an activator including at least one of Eu, Ce, Pr, Mn and Bi, or a compound thereof; and

x and y satisfy 0<x<1 and 0<y<0.9.

Meanwhile, light-emission function can be imparted to the phosphor by doping the activator described above.

The activator may be a chloride activator having a low decomposition temperature.

The chloride activator may be present in an amount of 0.1 wt % to 30 wt % with respect to the matrix.

Specifically, the chloride activator may be any one of EuCl₃, EuCl₂ and CeCl₃.

Hereinafter, a specific example of preparing the boron nitride (BN) phosphor will be described.

A variety of crystal structures based on boron nitride (BN) are present due to stable crystal structure of boron nitride (BN).

Various metal-boron nitride structures may be prepared by adding a metal to boron nitride, but this preparation is not easy.

The present invention provides a preparation method including forming a phosphor matrix at a low temperature and at a low pressure using a bivalent alkaline earth metal precursor such as Mg, Ca, Sr or Ba.

A metal-BN composition which has luminescent property using the metal-boron nitride (BN) crystal structures is suggested.

The composition of the metal-BN is represented by the following Formula 2:

M₃₋ₓB_{1-y}N_{3-2/3x-y} [Formula 2]

As described above, M represents an alkaline earth metal.

Regarding ingredients for synthesizing the substance having the composition described above, metal nitride is used instead of metals that are unstable in air and are explosive and hexagonal boron nitride (h-BN) is used as BN.

In the present invention, gas pressure sintering (GPS) capable of synthesizing phosphors using a low pressure of 1 MPa or less may be used instead of a conventional hot isostatic pressing (HIP) device requiring a GPa-scale high pressure.

Accordingly, the phosphor can be prepared at a relatively low temperature using the GPS method.

This process will be described in detail.

First, the preparation of the phosphor may be carried out within a pressure range of 0.1 to 0.9 MPa.

In addition, the production of the phosphor may be carried out by reacting at a temperature of 1,000° C. to 1,300° C. for 3 to 6 hours.

More specifically, the reaction may be carried out at a temperature of 1,200° C.

Upon increasing the temperature to the temperature range defined above, a rate of temperature increase per hour from the lower limit temperature to an intermediate temperature is greater than a rate of temperature increase per hour from the intermediate temperature to the upper limit temperature.

For example, when reaction is performed at 1,200° C., the temperature is increased at a high rate at 600° C. or less and at a low rate at 600° C. to 1,200° C. As such, the reason for increasing the temperature at different rates is that reaction of the precursor does not occur at the intermediate temperature or less.

More specifically, the temperature is increased at a rate of 5° C./min at 600° C. or less and at a rate of 2° C./min at 600° C. or more.

Similarly, temperature decrease after reaction may be also carried out in two stages.

For example, when the reaction is carried out at 1,200° C., the temperature is decreased at a low rate from 1,200° C. to 600° C. and at a high rate at 600° C. or less.

More specifically, the temperature is decreased at a rate of 2° C./min from 1,200° C. to 600° C. and at a rate of 5° C./min at 600° C. or less.

Through such a process, a total process time can be greatly reduced to 10 hours or less. That is, because reaction time may be greatly reduced and overlap the temperature increase time, the reaction time can be decreased to 10 hours or less.

This time is greatly shortened as compared to conventional general process time of 24 hours or longer.

Hereinafter, a specific example will be described.

### Example 1

### Synthesis of Mg₃BN₃ Structure

The synthesis process described above is performed using a combination of Mg₃N₂ and BN precursors.

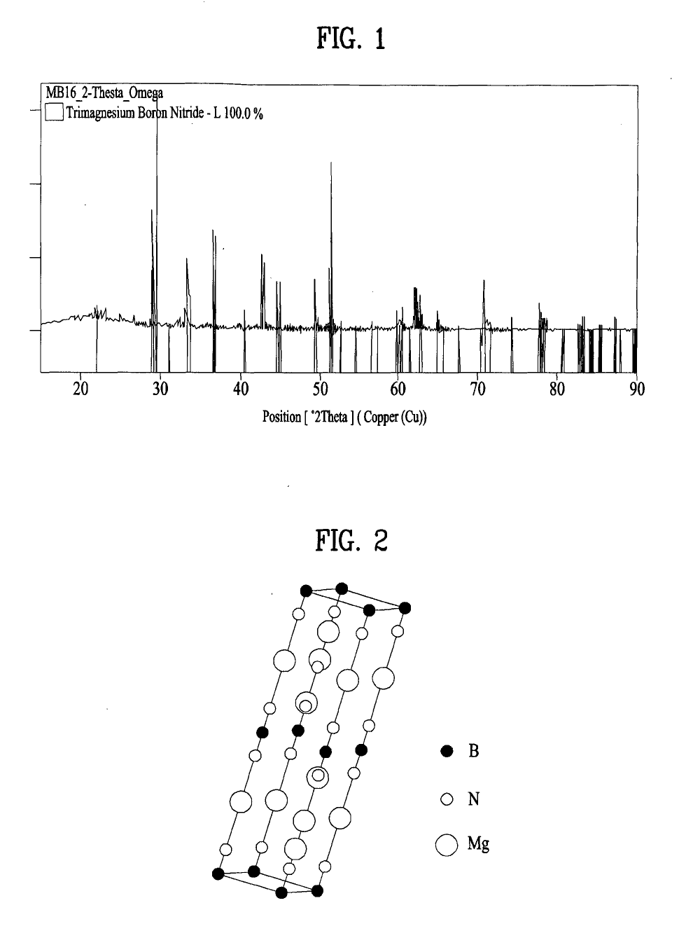

FIG. 1 illustrates an XRD spectrum of a synthesized Mg₃BN₃ structure. As can be seen from FIG. 1, the Mg₃BN₃ is synthesized in the same phase as the Mg₃BN₃ crystal structure of the P 63/mmc space group of a hexagonal crystal structure.

A model of such a crystal structure is shown in FIG. 2.

### Example 2

### Synthesis of Ca₃BN₄ Structure

The synthesis process described above is performed using a combination of 3Ca₃N₂ and 6BN precursors.

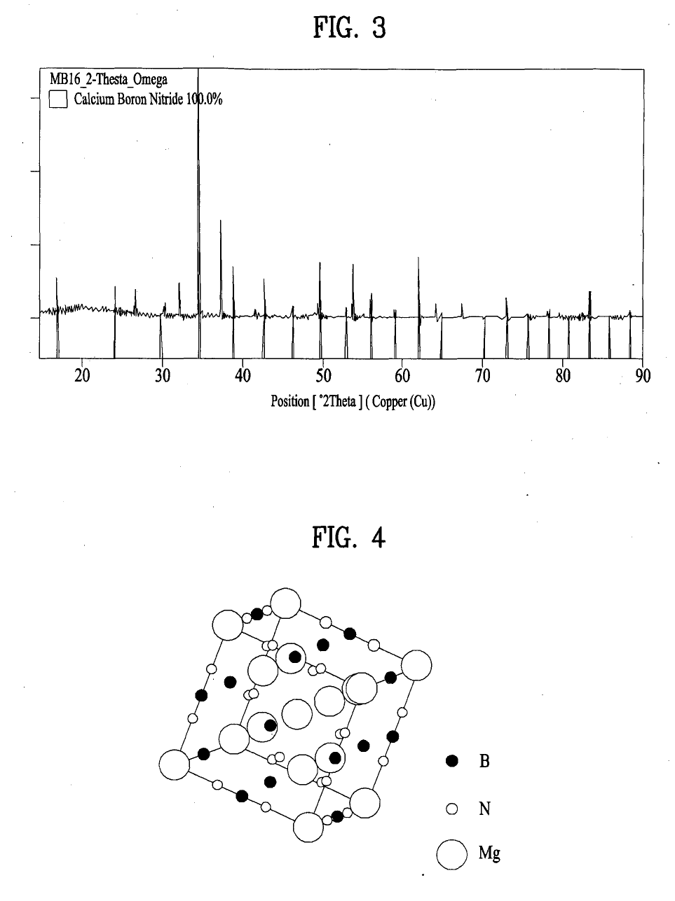

FIG. 3 illustrates an XRD spectrum of a synthesized Ca₃BN₄ structure. As can be seen from FIG. 3, the Mg₃BN₃ is synthesized in the same phase as the Ca₉(BN₂)₆ crystal structure of the Im-3m space group of a cubic crystal structure.

A model of such a crystal structure is shown in FIG. 4.

### Example 3

As shown in Examples 1 and 2 described above, the metal-BN structure could be prepared by a method different from a conventional method.

The metal-BN structure produced by the method described above is doped with an activator to impart the function of light emission to the metal-BN structure.

Generally used phosphors emit light by doping oxide or nitride-based crystal structures with a substance such as Eu, Ce, Tb, Mn or Sn as an activator.

Innumerable phosphor compositions for light emitting devices are present, but Mg₃BN₃ crystal phosphors capable of emitting light have yet to be developed. Accordingly, preparation of luminescent Mg₃BN₃ crystal phosphors is suggested.

Activators generally used in the related art include lanthanum oxides such as Eu₂O₃, CeO₂, Pr₂O₃, MnO₂ and Bi₂O₃.

However, in one embodiment according to the present invention, the Mg₃BN₃ phosphor composition is used for the phosphor by emitting light, as an activator, using a chloride precursor having a low decomposition temperature, because the Mg₃BN₃ structure is not doped with oxide having a high decomposition temperature due to a low synthesis temperature.

The activator used herein is any one of EuCl₃, EuC₁₂ and CeCl₃ and the activator is present in an amount of 0.1 wt % to 30 wt %, with respect to the weight of the matrix.

As such, emission of yellow and green light can be provided by light emission of Mg₃BN₃:Eu synthesized by applying EuCl₃ or EuCl₂ as an activator to Mg₃BN₃.

In this case, excitation light is derived from a near UV light source having a wavelength of 365 nm.

The phosphor is produced in the same manner as in Examples 1 and 2. In this case, a novel precursor substance having a certain composition which emits Mg₃BN₃ light using Mg₃N₂, BN, EuCl₃ and EuCl₂ as precursors and thereby serves as a phosphor is produced.

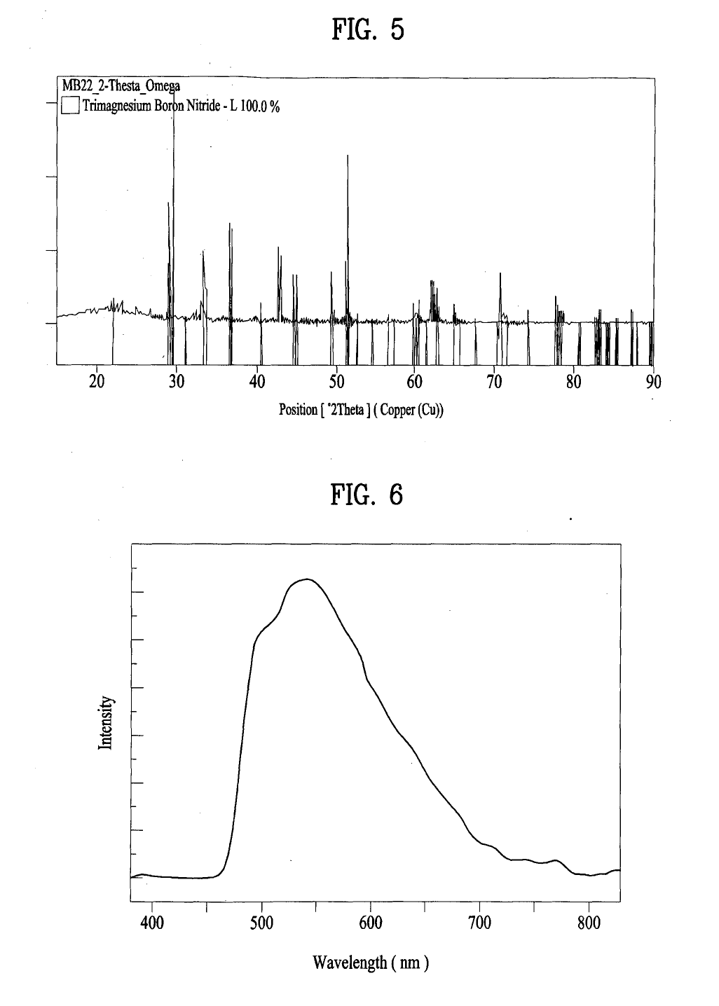

FIG. 5 illustrates an XRD spectrum of emitted Mg₃BN₃:Eu light. As can be seen from FIG. 5, Mg₃BN₃:Eu has the same phase as Mg₃BN₃. That is, Eu is completely substituted by Mg by doping.

FIG. 6 illustrates an emission spectrum of emitted Mg₃BN₃:Eu light, which shows green and yellow light emission.

In addition, it can be seen from the emission spectrum that orbital transition from d orbital to f orbital corresponds to emission resulting from the energy level of Eu²⁺ doped in the Mg site.

The phosphors using metal-BN crystal structures are novel phosphors that have been not found to date and may be used for light emitting devices or display devices.

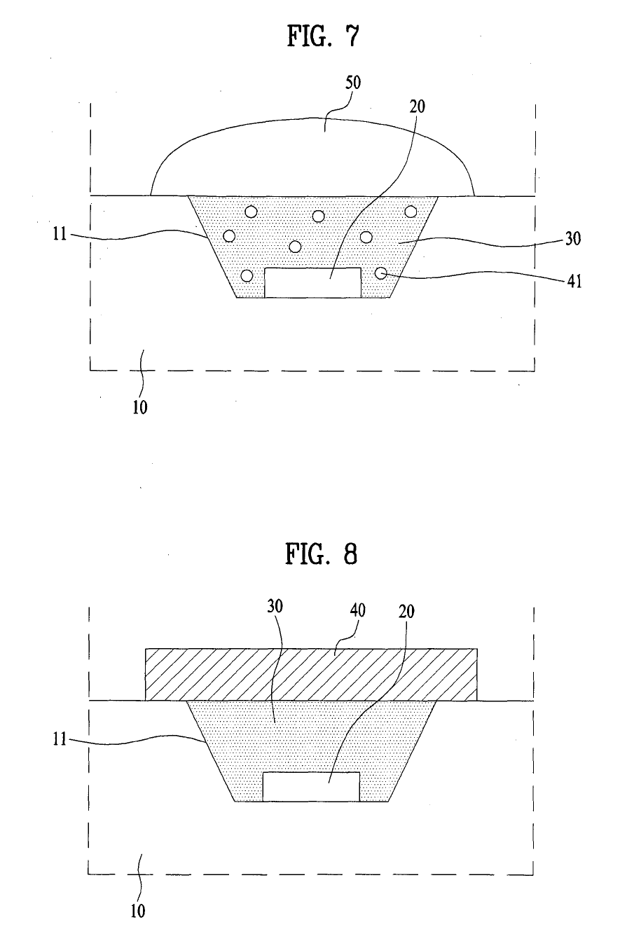

FIG. 7 illustrates an example of a light emitting device package using a metal-BN phosphor.

A light emitting device 20 is mounted inside a reflection cup 11 formed in a package body 10 and the metal-BN phosphor 41 is provided in a lower part of the light emitting device 20.

In this case, a filler 30 is disposed on the light emitting device 20 in the reflection cup 11 and a phosphor 41 is homogeneously mixed with the filler 30.

In addition, a lens 50 capable of focusing light emitted from the light emitting device 20 may be provided on the filler 30 and the phosphor 41.

FIG. 8 illustrates another example of a light emitting device package using a metal-BN phosphor.

As shown in the drawing, a phosphor layer 40 is separately produced using the metal-BN phosphor to constitute the light emitting device package.

That is, the light emitting device 20 is mounted inside the reflection cup 11 formed in the package body 10 and the filler 30 is disposed in an upper part of the light emitting device 20.

In this case, the phosphor layer 40 separated from the light emitting device 20 is disposed on the filler 30.

Examples in which the metal-BN phosphor is used for the light emitting device package have been described, but the metal-BN phosphor may be used for other display devices such as PDPs, CRTs and FEDs.

Meanwhile, it will be apparent to those skilled in the art that various modifications and variations can be made in the present invention without departing from the spirit or scope of the invention. Thus, it is intended that the present invention cover the modifications and variations of this invention provided they come within the scope of the appended claims and their equivalents.

### INDUSTRIAL APPLICABILITY

The present invention provides a metal-BN phosphor and a method for producing the same. The metal-BN substance has not yet reported as a phosphor, but the present invention provides a novel phosphor substance.

1. A boron nitride phosphor represented by the following Formula 1:
M₃₋ₓB_{1-y}N_{3-2/3x-y}:E [Formula 1]
wherein M represents an alkaline earth metal including at least one of Mg, Ca, Sr and Ba, and E represents an activator including at least one of Eu, Ce, Pr, Mn and Bi, or a compound thereof.

2. The boron nitride phosphor according to claim 1, wherein M represents Mg or Ca.

3. The boron nitride phosphor according to claim 1, wherein the activator is present in an amount of 0.1 wt % to 30 wt % with respect to the M₃₋ₓB_{1-y}N_{3-2/3x-y} matrix.

4. The boron nitride phosphor according to claim 1, wherein x and y satisfy 0<x<1 and 0<y<0.9.

5. A method for producing a boron nitride phosphor represented by the following Formula 1 using an alkaline earth metal, boron (B), nitrogen (N) and an activator.
M₃₋ₓB_{1-y}N_{3-2/3x-y}:E [Formula 1]
wherein M represents an alkaline earth metal including at least one of Mg, Ca, Sr and Ba, and E represents an activator including at least one of Eu, Ce, Pr, Mn and Bi, or a compound thereof.

6. The method according to claim 5, wherein the production of the phosphor is carried out by gas pressure sintering (GPS).

7. The method according to claim 5, wherein the production of the phosphor is carried out at a pressure of 0.1 to 0.9 MPa.

8. The method according to claim 5, wherein the production of the phosphor is carried out by reacting at a pressure of 1,000° C. to 1,300° C. for 3 to 6 hours.

9. The method according to claim 8, wherein, upon increasing the temperature to the temperature range defined above, a rate of temperature increase per hour from the lower limit temperature to an intermediate temperature is greater than a rate of temperature increase per hour from the intermediate temperature to the upper limit temperature.

10. The method according to claim 8, wherein, upon decreasing the temperature to the temperature range defined above, a rate of temperature decrease per hour from the upper limit temperature to the intermediate temperature is lower than a rate of temperature decrease per hour from the intermediate temperature to the lower limit temperature.

11. The method according to claim 5, wherein the activator comprises a chloride activator.

12. The method according to claim 5, wherein the alkaline earth metal is used as metal nitride.

13. The method according to claim 5, wherein the boron (B) and nitrogen (N) are used as hexagonal boron nitride.

14. A method for producing a boron nitride phosphor comprising:
forming a Mg₃BN₃ structure as a matrix using Mg₃N₂ and boron nitride (BN) as precursors; and
doping the matrix with an activator.

15. The method according to claim 14, wherein the boron nitride comprises hexagonal boron nitride.

16. The method according to claim 14, wherein the activator comprises a chloride activator.

17. The method according to claim 16, wherein the chloride activator comprises EuCl₃, EuCl₂ or CeCl₃.

18. The method according to claim 14, wherein the chloride activator is present in an amount of 0.1 wt % to 30 wt %, with respect to the weight of the matrix.

19. The method according to claim 14, wherein the production of the phosphor is carried out by gas pressure sintering (GPS).

20. A light emitting device package comprising the phosphor represented by Formula 1 according to claim 1, the phosphor represented by Formula 1 produced by the method according to claim 6 or a phosphor produced by the method according to claim 15.
